(19) United States
(12) Patent Application Publication
(10) Pub. No.: US 2017/0183795 A1
(43) Pub. Date: Jun. 29, 2017

(54) METHODS FOR ATOM INCORPORATION INTO MATERIALS USING A PLASMA AFTERGLOW

(71) Applicant: VALORISATION-RECHERCHE, LIMITED PARTNERSHIP, Montréal (CA)

(72) Inventors: Luc STAFFORD, Montréal (CA); Leron VANDSBURGER, Montréal (CA); Richard LEONELLI, Montréal (CA); Jason AFONSO-FERREIRA, Montréal (CA)

(73) Assignee: VALORISATION-RECHERCHE, LIMITED PARTNERSHIP, Montréal (CA)

(21) Appl. No.: 15/327,503

(22) PCT Filed: Jul. 23, 2015
(86) PCT No.: PCT/CA15/50693

§ 371 Date: Jan. 19, 2017

Related U.S. Application Data
(60) Provisional application No. 62/028,789, filed on Jul. 24, 2014.

(51) Int. Cl. C30B 31/20; C30B 31/08; H01L 21/02; H01J 37/32; H01L 33/00; H01L 29/16; H01L 21/223; C30B 29/40; H01L 29/20

(52) U.S. Cl. CPC C30B 31/20; C30B 29/406; C30B 31/08; H01L 21/02603; H01L 21/02664; H01L 29/2003; H01L 33/0075; H01L 29/1606; H01L 21/2236; H01J 37/32192; H01J 37/32706; H01J 2237/31701; H01J 2237/3165

(57) ABSTRACT

There are provided non-destructive methods for incorporating an atom such as N into a material such as graphene. The methods can comprise subjecting a gas comprising the atom to conditions to obtain a flowing plasma afterglow then exposing the material to the flowing plasma afterglow. There are also provided materials such as N-doped graphene produced by such methods.

The present application claims priority on U.S. 62/028,789 filed on Jul. 24, 2014, which is hereby incorporated by reference in its entirety.

The present disclosure relates to methods for atoms incorporation into a material using a plasma afterglow. For example, it relates to non-destructive methods for incorporating atoms such as nitrogen or a mixture of nitrogen and oxygen into highly sensitive nanomaterials such as nitride nanowires and graphene films using a late flowing afterglow.

The III-V nitride semiconductor family members and their alloys have been studied due to their particular properties that make them stand out from other conventional III-V semiconductors. For example, they have a higher electron mobility, are suitable for high-temperature applications, and exhibit wide direct bandgaps that may, for example, allow heterostructures (HSs) to be designed covering the electromagnetic spectrum from ultraviolet to infrared.¹ Such materials are thus found in a wide range of optoelectronic devices, in particular light-emitting diodes (LEDs)^{2,3} and laser diodes (LDs).⁴

There has been a growing interest in InGaN/GaN nanowire (NW) HSs as they may, for example, offer reduced defect densities because of lateral stress relaxation.⁵ III-V-nitride-based NWs may, for example, present a high-crystalline quality, a large surface-area-to-volume ratio, and the possibility to achieve quantum confinement. Therefore, the reduction of native defects, the enhancement of a larger active area as well as the presence of quantum dots in the HSs may, for example, lead to improved LED efficiency.

For example, Mi et al.⁶ designed InGaN/GaN dot-in-a-wire nanostructures to be used as sources of light. Strong green, yellow, and amber emission was obtained by varying the In composition in assembled HSs. They measured an internal quantum efficiency of about 45% at room-temperature⁷, which is much higher than the values achieved in conventional planar HSs.

Zhang et al.⁸ obtained an internal quantum efficiency in InGaN/GaN dot-in-a-wire of about 35% and a green emission centered at 490 nm. In addition, by varying the In composition during growth of the NWs, they efficiently designed white-emitting LEDs.⁹ Kikuchi et al.¹⁰ also fabricated LEDs based on GaN NWs with InGaN multiple quantum disks acting as active layer. Strong emission was measured which spanned from violet to red.

Surface modification of NWs may, for example, bestow them new or upgraded properties.^{11,12,13} As previously reported, the emission properties of GaN-based NWs are strongly affected by the presence of surface or bulk defects that can appear either during growth or after a post-growth treatment.

Because of their wide range of active species (photons, electrons, ions, excited species), plasmas may, for example, allow modification that cannot be obtained using conventional physical or chemical media. Post-growth treatment of GaN thin films using plasmas has been reported.¹⁴

For example, M.-G. Chen et al.¹⁵ have exposed n-GaN thin films to a low-pressure Ar plasma. They observed a significant decrease of the yellow-band defect and the GaN band edge emissions, which was attributed to the creation of nitrogen vacancies and non-radiative recombination centers on the GaN surface by ion bombardment. An increase of the blue emission related to defects in bulk GaN was also measured. S. Chen et al.¹⁶ have exposed GaN films damaged by a chlorine ion beam to a hydrogen plasma and observed 90% recovery of the GaN band edge emission. This result was attributed to a desorption of the chlorinated species in the damaged film as well as to a passivation of the free Ga atoms on the surface.

Graphene, a single layer of graphite, has raised interest in the scientific community for its useful thermal, mechanical, electrical and other properties. The electronic properties are a useful aspect of graphene, for example but not limited to, its ballistic transport properties and longest mean free path at room temperature, integral and half-integral quantum hall effect and the highest mobility to increase the speed of devices. The mobility of graphene is higher than that of the widely-used semiconductor Si. Consequently, graphene has been considered as a candidate material for applications in post-silicon electronics. However, most electronic applications are handicapped by the absence of a semiconducting gap in pristine graphene. One way of opening a bandgap in graphene is doping, which is generally achieved during growth, for example, by arc discharge or chemical vapor deposition.

Nitrogen doping in nanomaterials to date has been accomplished during growth by various physical and chemical methods. Conventional post-growth methods, which offer more versatility than variation of the growth conditions, are based either on wet chemical processes or direct implantation of nitrogen atoms. Known techniques for this latter process are plasma-based and rely on electrostatic acceleration of charged particles to high velocities, with subsequent “filtration” of the charged particles from the bombardment stream. In this way, neutral nitrogen atoms are directed at high-velocity towards a target surface, and the atoms are “forced” in. The advantage of targeted bombardment is a high degree of localization of incorporation on the surface of treated substrates. The undesirable side-effects of this approach are, for example, the extensive cascade of defects caused by atom bombardment, which is unavoidable when using accelerated-atom methods. Wet chemical approaches are limited to the topmost surface unless external energy supplies provide the activation energy required for “deep” incorporation in nanomaterials. The electrochemical methods used to achieve these aims are limited by the same issues faced by ion bombardment in low pressure applications, for the reason that the mechanism of action is similar, although acting through a more condensed phase. Furthermore, aqueous electrochemistry faces the further limitation of voltage induced hydrogen evolution, which inhibits surface functionalization.

For example, PCT Application Publication No. 2014/012600 discloses a process for preparing nitrogen-doped graphene comprising treating graphene oxide with a nitrogen-containing compound such as cyanamide and heating the resulting mixture. For example, the heating comprises an annealing step wherein the solid is heated at about 550° C. for 3 to 5 hours then heating the solid obtained from annealing at about 900° C. for 30 to 90 minutes.

For example, Shao et al.¹⁷ teach that nitrogen-doped graphene has been obtained by exposing graphene to nitrogen plasma. The “graphene” used in the experiments of Shao et al. is graphitic carbon flakes which were placed on a glassy carbon substrate and subjected to the nitrogen plasma.

For example, Felten et al.¹⁸ disclose the covalent modification of mono- and bilayer graphene using tetrafluoromethane, oxygen and hydrogen RF plasma. The plasma is used by Felten et al. to produce fragments from reactive gases that were grafted onto the graphene surface.

According to an aspect of the present disclosure, there is provided a method for atom incorporation into a material, comprising:
subjecting a gas comprising the atom to conditions to obtain a flowing plasma afterglow; and
exposing the material to the flowing plasma afterglow.

According to another aspect of the present disclosure, there is provided an atom-doped material prepared by a method for atom incorporation into a material of the present disclosure.

According to another aspect of the present disclosure, there is provided a method for decreasing defects in a nitride semiconductor nanostructure, comprising exposing said nitride semiconductor nanostructure to a flowing plasma afterglow of a plasma obtained from a gas comprising N₂.

According to another aspect of the present disclosure, there is provided a method for tuning the emission spectrum of a nitride semiconductor nanostructure, comprising exposing said nitride semiconductor nanostructure to a flowing plasma afterglow of a plasma obtained from a gas comprising N₂ and O₂.

In the following drawings, which represent by way of example only, various embodiments of the disclosure:

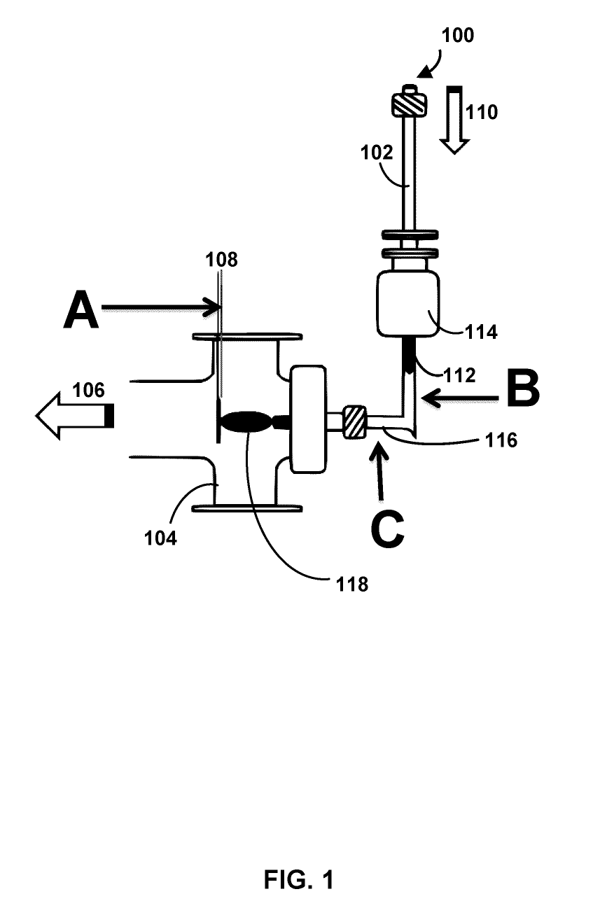

FIG. 1 is a schematic of a N₂ microwave discharge used to obtain a late afterglow in a stainless steel processing chamber according to an example of a method of the present disclosure;

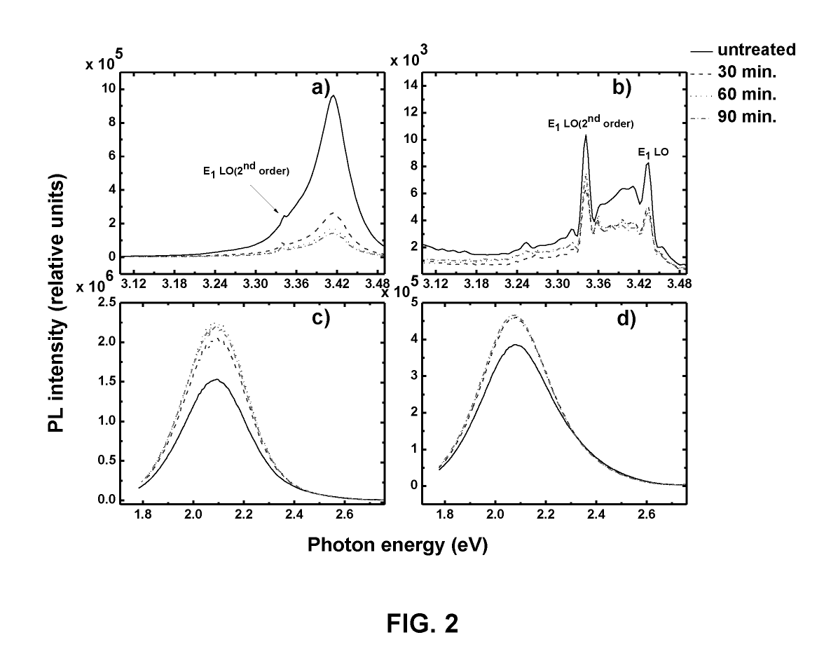

FIG. 2 shows the influence of treatment time to a N₂ late afterglow on the photoluminescence (PL)spectra from nominally pure GaN NWs and InGaN/GaN dot-in-a-wire nanostructures according to another example of a method of the present disclosure: (A) Band edge emission from GaN nanowires excited at 352 nm, (B) GaN emission from InGaN/GaN dot-in-a-wire nanostructures excited at 352 nm, (C) InGaN emission from InGaN/GaN dot-in-a-wire nanostructures excited at 352 nm, and (D) InGaN emission from InGaN/GaN dot-in-a-wire nanostructures excited at 405 nm (only emission from the InGaN core is presented since the GaN shell is transparent at 405 nm). For both samples, resonant Raman scattering peaks (first and second order E₁ LO mode) can also be observed;

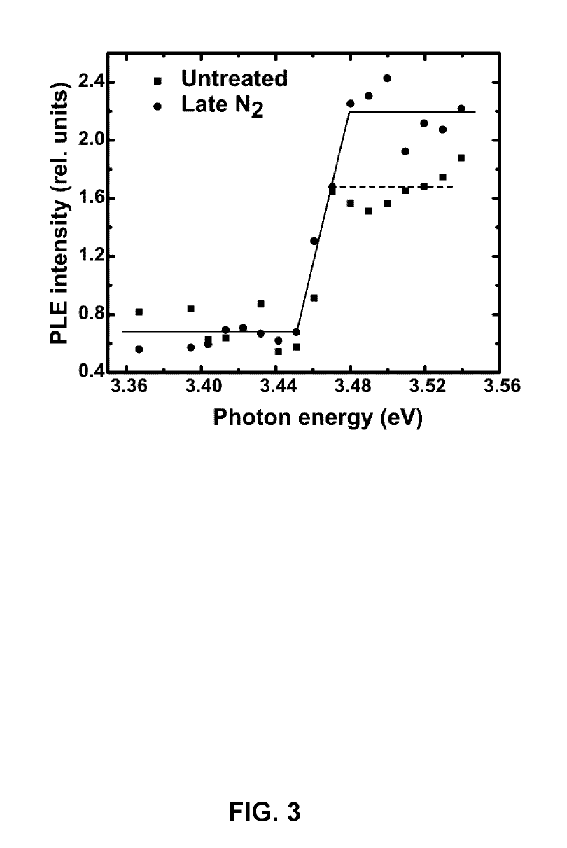

FIG. 3 shows exemplary photoluminescence excitation (PLE) spectra at the bandedge emission of InGaN (595 nm) from InGaN/GaN nanowires treated for 90 minutes with the late afterglow of a microwave N₂ plasma according to another example of a method of the present disclosure (•) and from untreated InGaN/GaN nanowires (▪). The lines are to guide the eye;

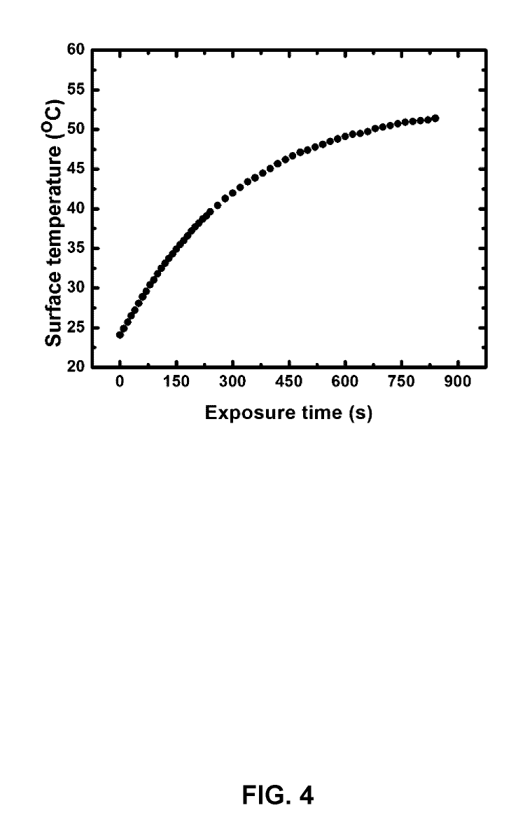

FIG. 4 shows the temperature of the substrate holder as a function of exposure time (seconds) recorded with a thermocouple following exposure to the late afterglow of a microwave N₂ plasma according to another example of a method of the present disclosure;

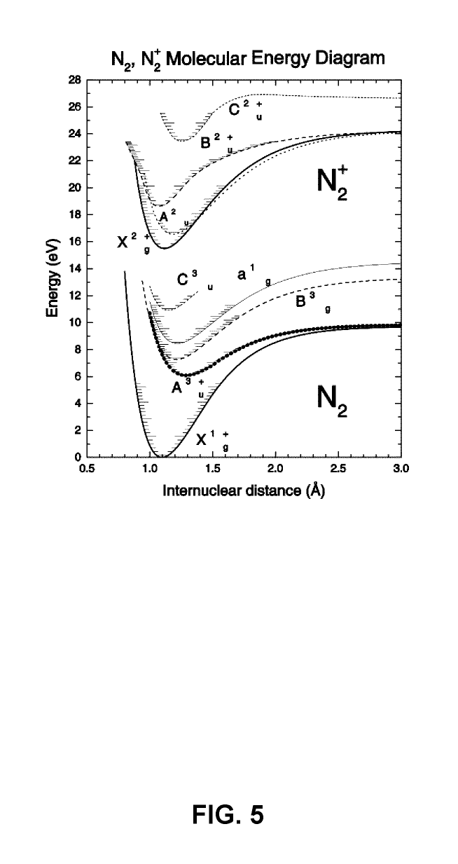

FIG. 5 is a schematic showing the molecular energy level diagrams for N₂⁺ (top) and N₂ (bottom). The metastable state, N₂ (A), is identified as the carrier of chemical energy in a method of the present disclosure;

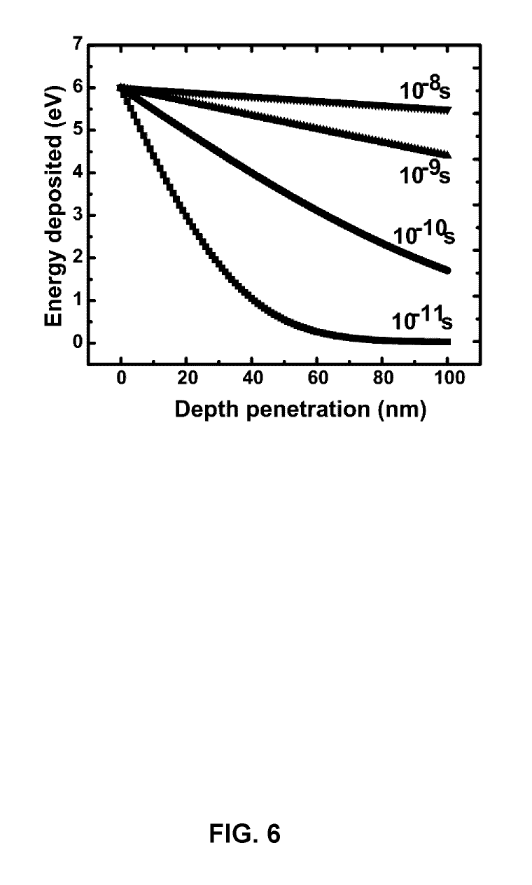

FIG. 6 shows the solution of the heat-transfer equation in 1-dimension for the energy deposited by the de-excitation of N₂(A) metastables by collision with a 100-nm thick GaN sample according to another example of a method of the present disclosure. The results are shown for different diffusion times after deposition of the localized source of heat on the topmost surface (6 eV);

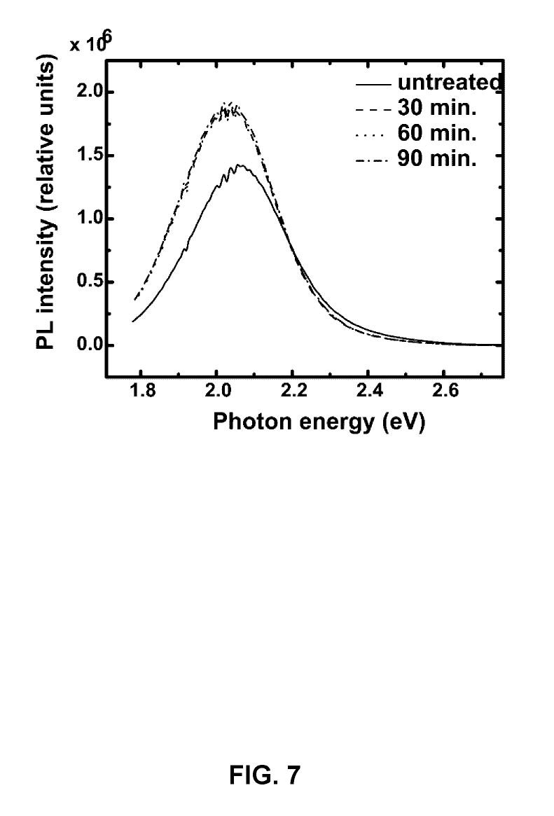

FIG. 7 shows exemplary photoluminescence spectra from InGaN inclusions in InGaN/GaN dot-in-a-wire nanostructures excited at 352 nm after treatment to the late afterglow of a N₂—O₂ plasma according to another example of a method of the present disclosure;

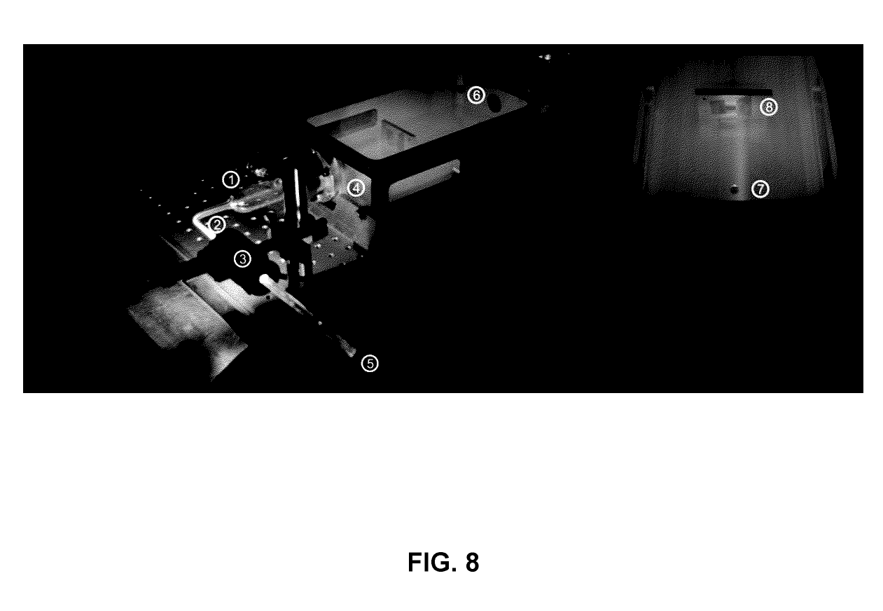

FIG. 8 shows exemplary photographs of the plasma-based process used to functionalize graphene with the late afterglow of a N₂ plasma according to another example of a method of the present disclosure;

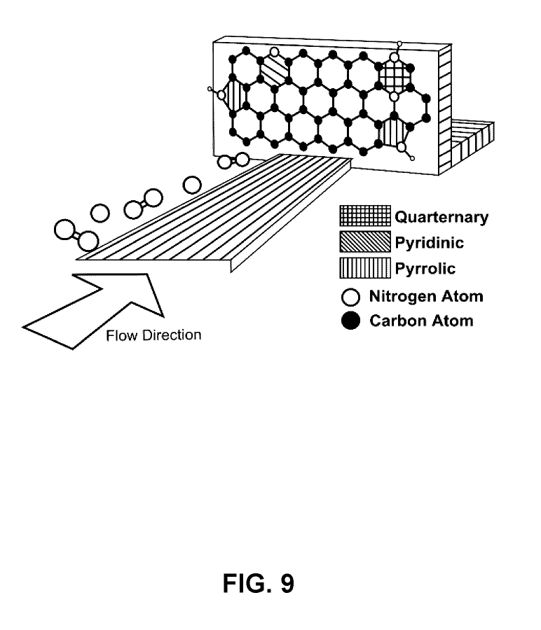

FIG. 9 is a schematic diagram showing the chemical process occurring when graphene is functionalized with the late afterglow of a N₂ plasma according to another example of a method of the present disclosure;

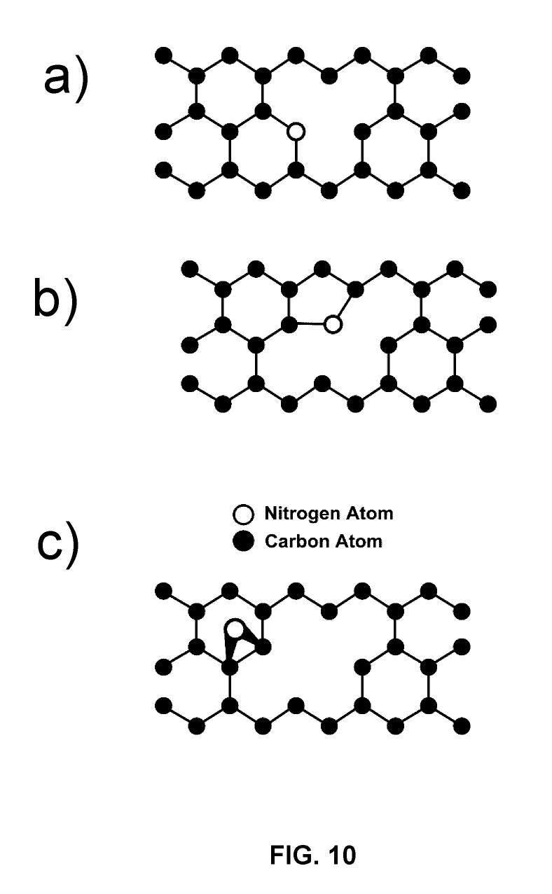

FIGS. 10a, 10b and 10c are molecular representations of three types of induced N groups into host material according to another example of a method of the present disclosure in which FIG. 10a represents Pyridinic N; FIG. 10b represents pyrrolic N, and 10c represents aziridinic N;

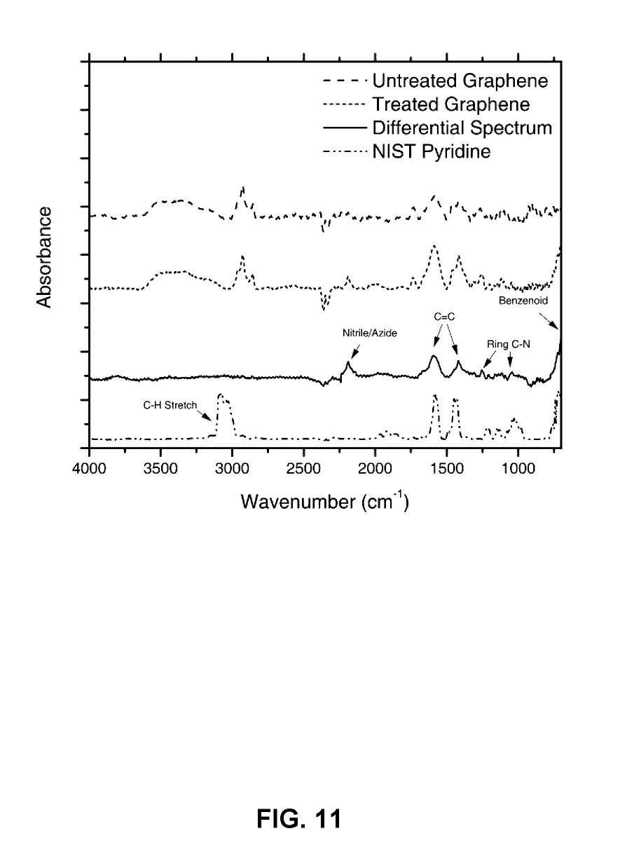

FIG. 11 shows exemplary FTIR spectra from graphene samples exposed to the late afterglow of N₂ plasmas according to another example of a method of the present disclosure;

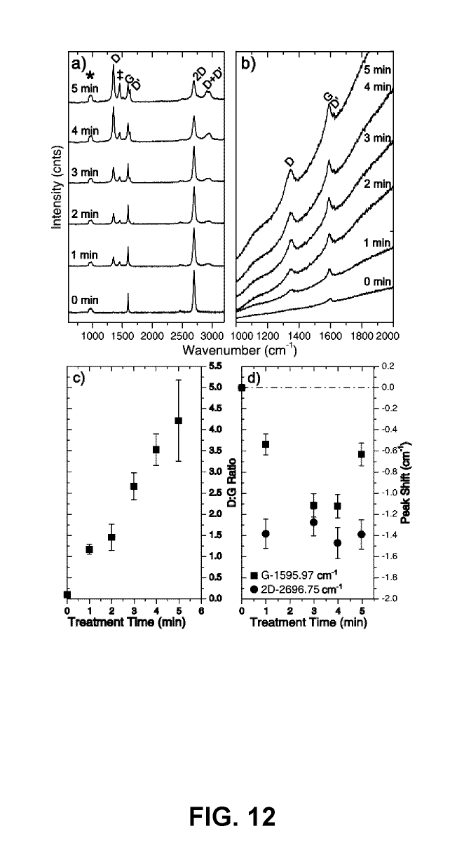

FIG. 12 shows exemplary Raman spectra from graphene samples exposed to the late afterglow of N₂ plasmas according to another example of a method of the present disclosure;

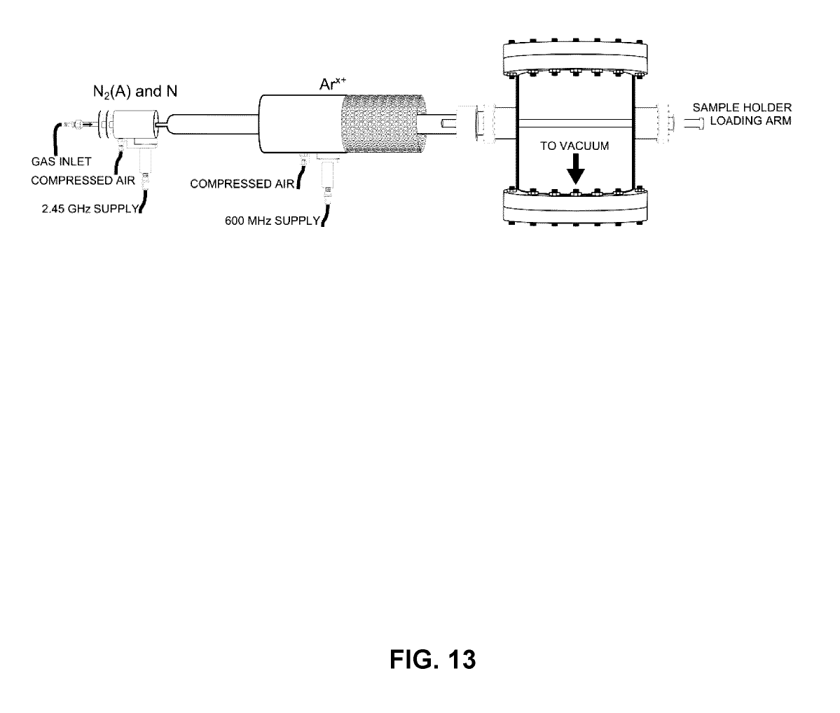

FIG. 13 is a schematic representation of a dual N₂—Ar plasma system according to an example of a method of the present disclosure;

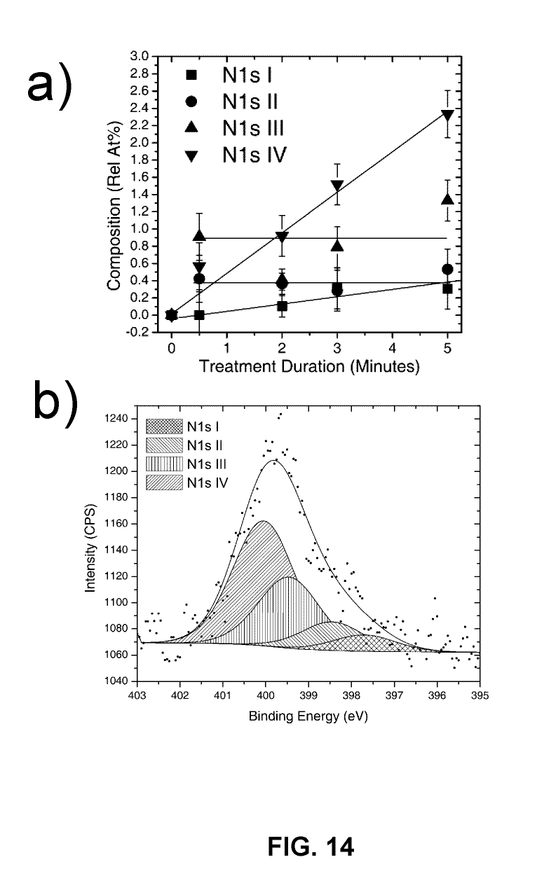

FIGS. 14a and 14b show exemplary XPS data, showing the presence of aromatic nitrogen atoms according to another example of a method of the present disclosure;

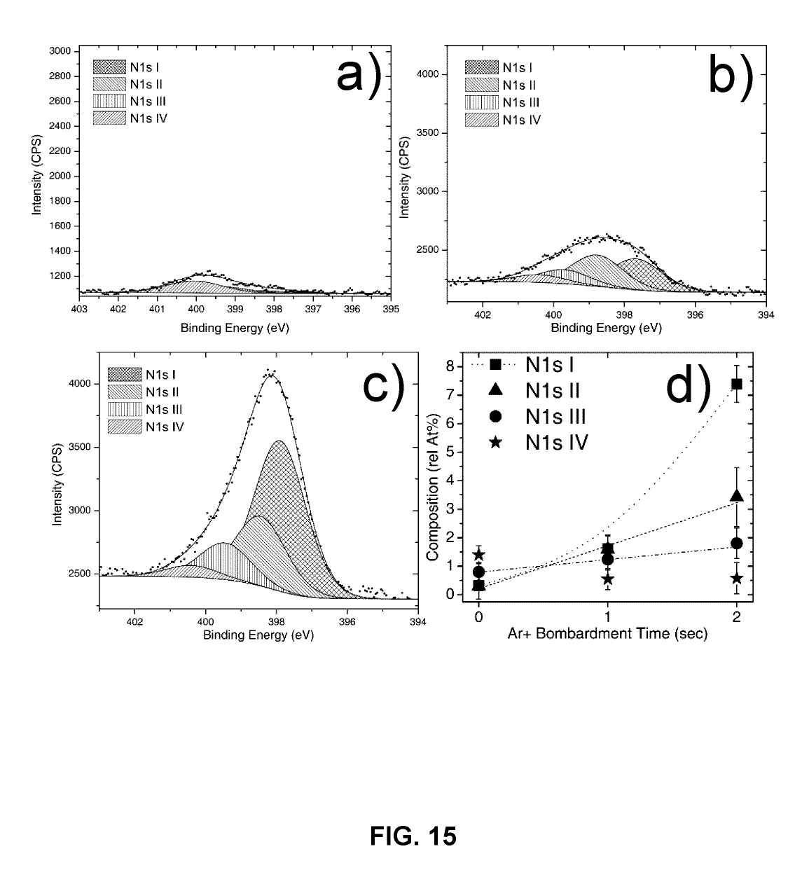

FIGS. 15a, 15b and 15c show exemplary XPS data, showing the presence of aromatic nitrogen atoms while FIG. 15d shows the relative at percentage values for the process of ion bombardment data, calculated by XPS, according to another example of a method of the present disclosure;

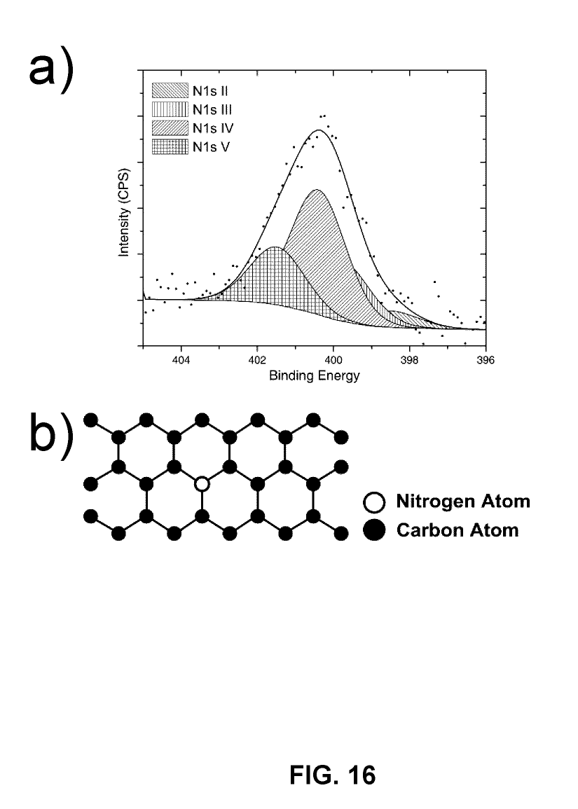

FIG. 16a shows exemplary XPS data, showing the presence of aromatic nitrogen atoms while FIG. 16b is a graphic demonstrating the type of group induced, according to another example of a method of the present disclosure;

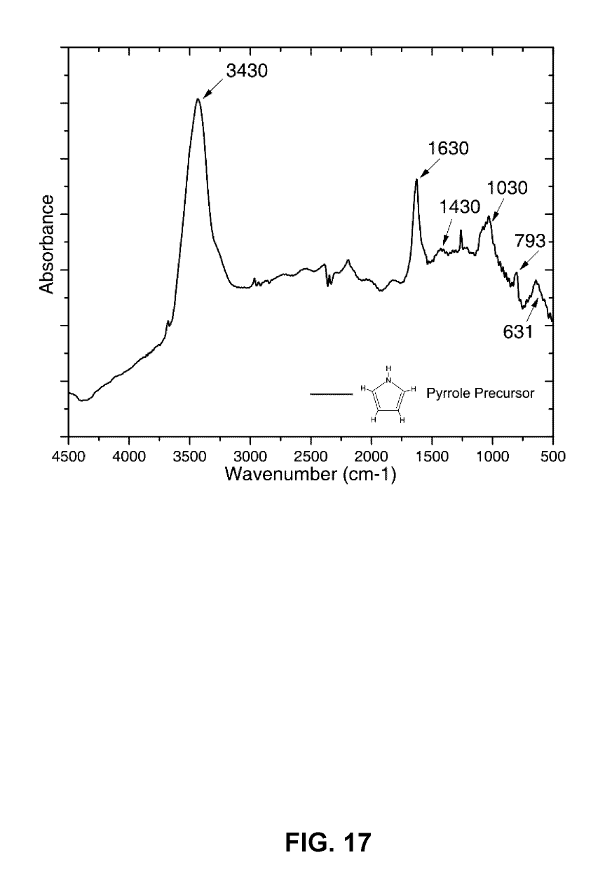

FIG. 17 is a FTIR spectra showing molecular structure of plasma deposited film using a pyrrole monomer according to another example of a method of the present disclosure;

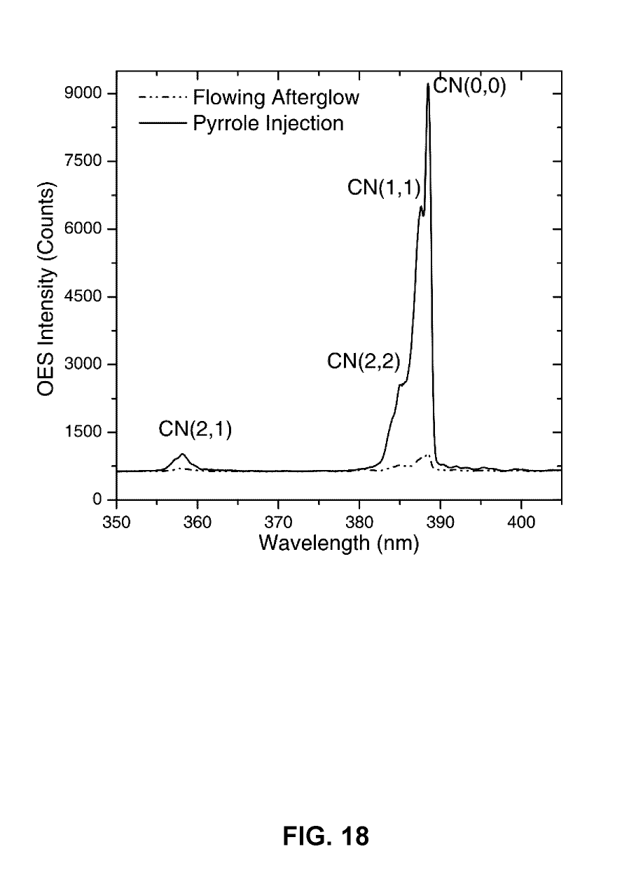

FIG. 18 is an Optical Emission Spectrum (OES) of the plasma at the point of injection, showing excited vibrational states of CN, according to another example of a method of the present disclosure;

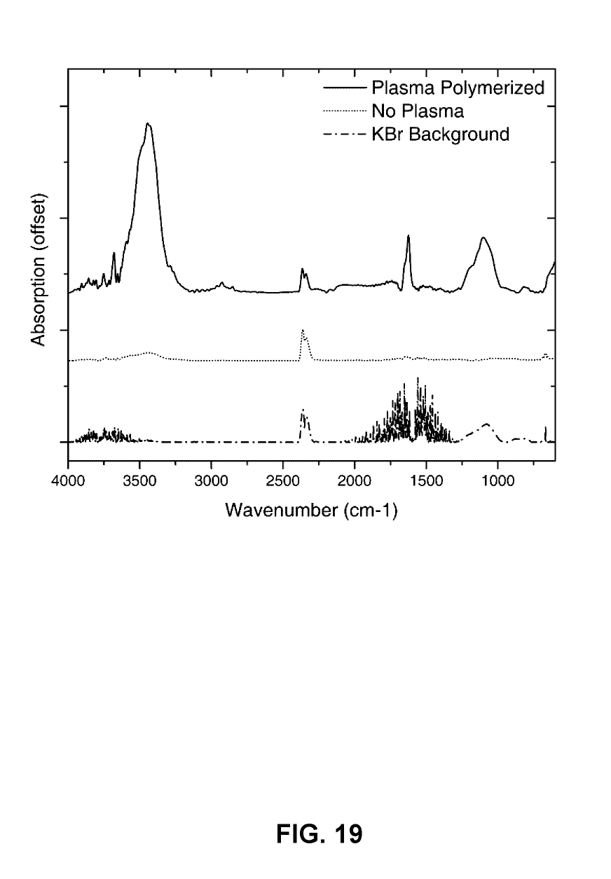

FIG. 19 is a FTIR spectra showing role of plasma polymerization in film structure, according to another example of a method of the present disclosure; and

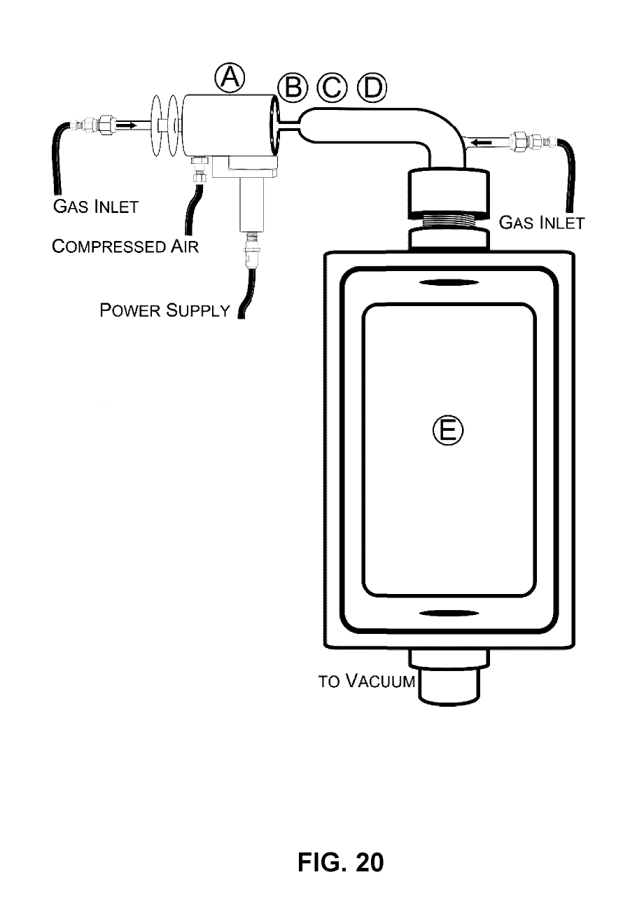

FIG. 20 is a schematic representation of a system according to an example of a method of the present disclosure;

Unless otherwise indicated, the definitions and embodiments described in this and other sections are intended to be applicable to all embodiments and aspects of the present disclosure herein described for which they are suitable as would be understood by a person skilled in the art.

As used in the present disclosure, the singular forms “a”, “an” and “the” include plural references unless the content clearly dictates otherwise. For example, an embodiment including “an atom” should be understood to present certain aspects with one atom, or two or more additional atoms.

In embodiments comprising an “additional” or “second” component, such as an additional or second atom, the second component as used herein is different from the other components or first component. A “third” component is different from the other, first, and second components, and further enumerated or “additional” components are similarly different.

In understanding the scope of the present disclosure, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. The term “consisting” and its derivatives, as used herein, are intended to be closed terms that specify the presence of the stated features, elements, components, groups, integers, and/or steps, but exclude the presence of other unstated features, elements, components, groups, integers and/or steps. The term “consisting essentially of”, as used herein, is intended to specify the presence of the stated features, elements, components, groups, integers, and/or steps as well as those that do not materially affect the basic and novel characteristic(s) of features, elements, components, groups, integers, and/or steps.

Terms of degree such as “about” and “approximately” as used herein mean a reasonable amount of deviation of the modified term such that the end result is not significantly changed. These terms of degree should be construed as including a deviation of ±10% of the modified term if this deviation would not negate the meaning of the word it modifies.

The term “graphene” as used herein includes, for example, graphene flakes, bilayer graphene, single-layer graphene, multilayer graphene, and carbon nanotubes.

The term “atom incorporation” as used herein means, for example, that the atom is incorporated into the host material either as an interstitial atom or via the formation of one or more chemical bonds between the atom and atom(s) in the host material. This is different from surface functionalization, where atoms are attached by chemical bonds to the outer surface atom(s) of the host material. It will be appreciated by a person skilled in the art that the nature of the chemical bond will depend on the atom incorporated and the host material. For example, in the case of nitrogen incorporation into graphene, covalent bonds are typically formed.

The expression “non-destructive method” as used herein when referring to a method for incorporating an atom into a material refers, for example, to a method that will cause substantially no disordering in the target material as a result of treatment. For example, a treatment method is considered non-destructive when the native properties of the target material are not substantially lost after treatment, while its desired chemical results are accomplished. For example, in the case of graphene modification, a non-destructive method does not interrupt the graphene lattice (macromolecular structure) (for example as shown by the types of bonds induced in the sample (FIG. 12) and the residual large area sp² hybridization (FIG. 11)). For example, destruction of the graphene macromolecular structure would eliminate these signatures of aromaticity. In the same way, a non-destructive method will, for example, allow the GaN nanowires to retain their native optical properties after treatment, as evidenced by the PL spectra (see FIG. 2).

The below presented examples are non-limitative and are used to better exemplify the processes of the present disclosure.

For example, the gas can be subjected to an electromagnetic surface wave to obtain the flowing plasma afterglow.

For example, the gas can be subjected to an electromagnetic field in the microwave regime to obtain a high-density plasma with a flowing plasma afterglow.

For example, the electromagnetic field can have a frequency of about 433 MHz to about 3 GHz. For example, the electromagnetic surface wave can have a frequency of about 2450 MHz.

For example, the electromagnetic surface wave can be launched by a gap-type wave launcher.

For example, the absorbed power supplied to the plasma by a microwave power source can be about 30 W.

For example, the atom incorporated into the material can be N, O, B, H or mixtures thereof and the gas can comprise, consist essentially of or consist of N₂, O₂, B₂H₆, H₂ or mixtures thereof, respectively. For example, the atom incorporated into the material can be a mixture of N and O and the gas can comprise, consist essentially of or consist of a mixture of N₂ and O₂. For example, the atom incorporated into the material can be N and the gas can comprise, consist essentially of or consist of N₂.

For example, the plasma can comprise argon or other noble gases

It will be appreciated by a person skilled in the art that varying the mass flow rate of the gas and/or the total gas pressure may, for example, adjust the location of the early afterglow and late afterglow in the methods for atom incorporation into a material of the present disclosure. The selection of a volumetric flow rate and total gas pressure so that the material is exposed to a particular flowing plasma afterglow can be made by a person skilled in the art.

For example, the gas can be provided at a volumetric flow rate of about 100 SCCM (Standard Cubic Centimeters per Minute). For example, the gas can be provided at a volumetric flow rate of about 1 SCCM to about 5000 SCCM. For example, the gas can be provided at a volumetric flow rate of about 100 or about 250 SCCM. For example, a second gas can be provided at a volumetric flow rate of about 1 to about 30 SCCM.

For example, the method can be carried out at a total gas pressure of from about 1 Torr to about 20 Torr, about 2 Torr to about 18 Torr, or about 4 Torr to about 16 Torr. For example, the method can be carried out at a total gas pressure of about 10 Torr.

For example, the flowing plasma afterglow can be a late afterglow.

For example, the flowing plasma afterglow can have a positive ion density of about 10⁵ cm⁻³ to about 10¹⁰ cm⁻³. For example, the flowing plasma afterglow can have a positive ion density of about 10⁷ cm⁻³.

For example, the material can be exposed to the flowing plasma afterglow at a temperature of less than about 55° C. For example, the material can be exposed to the flowing plasma afterglow at a temperature of from about 25° C. to about 80° C.

For example, the material can be exposed to the flowing plasma afterglow for a time of less than about 90 minutes. For example, the material can be exposed to the flowing plasma afterglow for a time of about 0.1 to about 90 minutes.

For example, the material can be exposed to the flowing plasma afterglow using flow vectoring. It will be appreciated by a person skilled in the art that flow vectoring is a concept commonly used when handling working flows, for example, in modern military aircraft. Since the species of interest are entrained in the flowing afterglow and reach the target surface by that flow, exposure of the sample to the species of interest can be achieved by manipulating the direction of flow. Because, for example, the late afterglow is essentially at room temperature and does not contain highly energetic species, the flow can, for example, be scanned across the target surface, for example, by means of a versatile nozzle.

For example, the material can be exposed to the flowing plasma afterglow in a chamber.

For example, the material can comprise, consist essentially of or consist of graphene, a nanomaterial, a metal surface, a crystal surface, a polymer or a combination thereof.

For example, the material can comprise, consist essentially of or consist of graphene.

For example, the material can comprise graphene and copper, nickel, diamond or sapphire.

For example, the material can comprise graphene and copper.

For example, the material can comprise graphene grown on a copper foil.

For example, the material can comprise, consist essentially of or consist of a nanomaterial. For example, the nanomaterial can comprise, consist essentially of or consist of nanowires, nanotubes, or nanofilms, or mixtures thereof. For example, the nanomaterial can comprise, consist essentially of or consist of an InGaN/GaN dot-in-a-wire nanostructure.

For example, the atom incorporated into said material can be N, thereby forming N-containing aromatic groups.

For example, the atom incorporated into said material can be N, thereby forming N-containing heterocycles.

For example, the atom incorporated into said material can be N, thereby forming pyridinic groups.

For example, the atom incorporated into said material can be N, thereby forming pyrrolic groups.

For example, the atom incorporated into said material can be N, thereby forming amide groups.

For example, the atom incorporated into said material can be N, thereby forming amine groups.

For example, the atom incorporated into said material can be N, thereby forming aziridinic groups.

For example, the atom incorporated into said material can be N, thereby forming adsorbed N atoms at the surface said material.

For example, the atom incorporated into said material can be N, thereby forming adsorbed N atoms into said material.

For example, the atom incorporated into said material can be N, thereby forming tertiary amines.

For example, the atom incorporated into said material can be N, thereby forming quaternary amines.

For example, the method can further comprise bombarding said material with ions.

For example, the method can further comprise treating said material with ions bombardment so as to increase defect density into said material and/or atom incorporation into said material.

For example, the method can comprise applying a DC voltage on a holder for holding said material so as to accelerate inert positive ions to the surface of said material.

For example, the method can comprise applying a DC voltage between 0 VDC and −200 VDC on a holder for holding said material so as to accelerate inert positive ions to the surface of said material.

For example, the method can comprise, before exposing said material to said flowing plasma afterglow, contacting said plasma afterglow with a precursor or polymerizable moiety effective for polymerizing.

For example, the precursor or polymerizable moiety can be a carbon-containing substance.

For example, the method can comprise, before exposing said material to said flowing plasma afterglow, contacting said plasma afterglow with a carbon-containing substance effective for polymerizing.

For example, the method can comprise, before exposing said material to said flowing plasma afterglow, contacting said plasma afterglow with a carbon-containing substance effective for polymerizing, thereby forming polymerized macromolecules on a surface of said material.

For example, the carbon-containing substance can be a C2-C12 carbon-containing substance.

For example, the carbon-containing substance can be a C2-C6 carbon-containing substance.

For example, the carbon-containing substance can be a linear or branched hydrocarbon.

For example, the carbon-containing substance can be a cyclic hydrocarbon.

For example, the carbon-containing substance can be an aromatic hydrocarbon.

For example, the carbon-containing substance can be chosen from ethane, ethylene, benzene, pyrrole, and pyridine.

For example, the carbon-containing substance can be chosen from pyrrole, and pyridine.

For example, the method can be carried out by allowing UV light to contact said material.

For example, the method can be carried out by at least substantially preventing UV light to contact said material.

For example, the method can be carried out in less than 20, less than 15, less than 10, or less than 5 minutes.

For example, the method can be carried out in about 1 to about 15 minutes, about 1 to about 10 or about 1 to about 5 minutes.

It will be appreciated by a person skilled in the art that embodiments relating to the atom-doped materials of the present disclosure can be varied as discussed herein for the embodiments of the methods for atom incorporation into a material of the present disclosure.

For example, the atom-doped material can be nitrogen-doped graphene. For example, the atom-doped material can be nitrogen- and oxygen-doped graphene. For example, the atom-doped material can be a nitrogen-doped InGaN/GaN dot-in-a-wire nanostructure. For example, the atom-doped material can be a nitrogen- and oxygen-doped InGaN/GaN dot-in-a-wire nanostructure.

### EXAMPLES

### Example 1

### Improvement of the Emission Properties from InGaN/GaN Dot-in-a-Wire Nanostructures After Treatment in the Flowing Afterglow of a Microwave N₂ Plasma

In this study, a new approach for post-growth functionalization of GaN-based NWs was explored. GaN NWs with and without InGaN insertions were exposed to the flowing afterglow of a microwave plasma operated in nominally pure N₂. Plasma-induced modification of InGaN/GaN nanowires was analyzed by photoluminescence (PL) and photoluminescence excitation (PLE) measurements performed at room temperature.

A purpose of the research was to explore adjusting the emission properties from InGaN/GaN dot-in-a-wire nanostructures using low-pressure plasmas. Conventional low-pressure plasmas, used for the deposition and etching of thin films in the microelectronic and optical industries, are very aggressive due to the presence of highly energetic ions. These ionic species with high kinetic energies are known to produce an extensive cascade of defects in materials following their impact with the surface, which is inappropriate for fine-tuning of highly sensitive nanomaterials such as InGaN/GaN dot-in-a-wire nanostructures

Nominally pure GaN nanowires and InGaN/GaN dot-in-a-wire heterostructures were exposed to the late afterglow of a N₂ microwave plasma and characterized by photoluminescence. While the band edge emission from GaN nanowires and the GaN matrix of the InGaN/GaN nanowires strongly decreased due to the creation of non-radiative recombination centers in the near-surface region, the emission from the InGaN dots strongly increased. While not wishing to be limited by theory, photoluminescence excitation measurements indicate that such an increase cannot be explained by a plasma-induced shift of the GaN absorption edge. It is ascribed to be a dynamical annealing process induced by the de-excitation of N₂ metastables following their collision with the nanowire surface. This set of data is the first experimental evidence that plasma-induced modification of the InGaN/GaN dot-in-a-wire nanostructures are not limited to the near-surface region of the GaN shell but extends all the way to the InGaN inclusions. While not wishing to be limited by theory, it is proposed that the adsorption of reactive N atoms and their transport inside the nanostructure passivate grown-in defects (in particular N vacancies) and the activation energy required for such N incorporation results from the de-excitation of N₂ metastable species following their interaction with the GaN surface.

I. Experimental Details

Nominally pure GaN nanowires and InGaN/GaN dot-in-a-wire heterostructures were epitaxially grown on Si(111) substrates by plasma-assisted molecular beam epitaxy as described elsewhere.^{19,20} Field-emission scanning electron microscopy⁷ showed that the wires are vertically aligned with diameters in the range of 30-50 nm and an areal density of ˜10¹⁰ cm⁻². The dot-in-a-wire HS consists of three vertically aligned quantum dots with a thickness of ˜8 nm, separated by a 5 nm-thick GaN barrier, buried in the GaN column. The average In composition of the insertions is ˜20%⁷ However, high-resolution transmission electron microscopy (TEM) images indicate the presence of In-rich nanoclusters formed by phase segregation, with sizes that vary from 2 to 5 nm and In composition in the 20-40% range. TEM performed on a single NW reveals that the InGaN dots are completely embedded in the GaN in the center region of the wire.

A schematic of the experimental apparatus 100 used for plasma-induced modification of GaN-based NWs is presented in FIG. 1. It is made up of a 0.6 cm inner diameter (0.8 cm outer diameter), 36 cm long fused silica tube 102 connected to a stainless steel processing chamber 104. A turbomolecular pump (not shown) evacuates 106 the whole system, yielding a base pressure in the 10⁻⁷ Torr range. A grounded substrate holder 108 made of stainless steel is inserted in the processing chamber 104 as shown in FIG. 1. N₂ gas is supplied through the gas inlet 110. Unless otherwise specified, the volumetric flow rate of N₂ was fixed at 250 Standard Cubic Centimeters per Minute (SCCM). For all experiments reported in this example, the total gas pressure, adjusted using a throttle valve (not shown) located at the pumping system and measured with a capacitance manometer placed downstream in the processing chamber, was fixed to 10 Torr. The plasma 112 was generated by the propagation of an electromagnetic surface wave at 2450 MHz. The wave was launched using a gap-type wave launcher, namely a surfatron²¹ 114, located 25 cm from the end of the discharge tube 102 (18 cm from the processing chamber). Microwave power was supplied by a Microtron (Electromedical supply) magnetron generator (not shown). The absorbed (incident minus reflected power) was set to 30 W, producing a surface-wave plasma (without the afterglows) with a length in front of the wave launcher of about 2 cm. For pressures in the 1-10 Torr range and relatively high gas flow rates (>100 SCCM), two distinct regions appear in the flowing afterglow of N₂ plasmas: the early afterglow (also called pink afterglow) 116 and the late afterglow 118 (see FIG. 1). The tube 102 is bent to prevent emission from the main plasma 112 (close to the wave launcher 114) to reach the downstream afterglow regions (116, 118). Both afterglows (116, 118) are linked to the N₂ vibration-vibration pumping mechanism, which creates highly energetic vibrational states (N₂(X, v≧15) that are pushed downstream by the high gas flows. These highly energetic N₂(X) states can collide to form N₂(A) and N₂(a′) metastables and then ion-electron pairs by associative ionization reactions²². Such an increase of the population of charged particles well beyond the main plasma region 112 characterizes the early afterglow 116. On the other hand, in the late afterglow 118, the population of positive ions drops significantly. As discussed elsewhere^{23,24}, at 10 Torr and for a N₂ volumetric flow rate of 250 SCCM, the substrate holder 108, where GaN-based NWs (not shown) are placed, is exposed to the late afterglow 118. The person skilled in the art would understand that various other material than GaN-based NWs can be used as material. Positive ion densities in this region are much below 10⁷ cm⁻³,²⁴ which is much lower than the values achieved in the main plasma region 112 (>10¹¹ cm⁻³) as well as in other types of low-pressure plasma reactors (typically between 10¹⁰ and 10¹¹ cm⁻³). Plasma-induced modifications are thus expected to be dominated by interactions with ground state atoms and molecules (N₂(X) and N(⁴S)) as well as with N₂(A) metastables (the population of N₂(A) is generally much higher than the one of N₂(a′).¹³

PL spectra were collected at room temperature using the frequency-doubled output of a continuous-wave Ti:sapphire ring laser as the excitation source. The excitation wavelength was set at 352 nm (photon energy of 3.52 eV), slightly above the GaN band gap of 3.4 eV, and the excitation power was stabilized at 80-90 mW. For an unfocused spot size of 2 mm, this yields a power density of 25-29 mW/mm². Most of this laser energy is reflected by the Si substrate, which ensures minimal sample heating during PL experiments.

The 405 nm line (photon energy of 3.06 eV) of a 50 mW InGaN laser was also used to perform direct excitation of the InGaN inclusions. PL spectra were analyzed with a 1 m double spectrometer and detected with a GaAs photomultiplicator using the standard single photon counting technique. Photoluminescence excitation (PLE) spectra were obtained using the monochromatized output of a Xe lamp. The intensity of the peak emission of the NWs (590 nm, photon energy of 2.1 eV) was then recorded using a 0.5 m spectrometer equipped with a charged-coupled device camera.

For example, in FIG. 1, at (A), the substrate holder can be biased with a set DC voltage between 0 VDC and −200 VDC to accelerate inert positive ions to the surface as a means of causing defects in target materials, such as graphene targets or graphene films.

For example, in FIG. 1, at (B), the same or a second microwave source could be added to produce a plasma using an inert gas, such as argon, to provide inert positive ions for the previously mentioned purpose.

For example, in FIG. 1, at (C), a source of gaseous or vaporised chemical precursor can be injected into the flowing afterglow as a means of depositing a polymer film coating on the graphene samples

II. Results and Discussion

InGaN/GaN dot-in-a-wire HSs and nominally pure GaN NWs were exposed to the N₂ late afterglow for sequential periods of 30 minutes. Between each exposure, PL spectroscopy was performed on the exposed samples as well as on an as-grown sample whose spectrum served as a reference for intensity calibration (relative units). FIG. 2 shows the PL spectra from both InGaN/GaN dot-in-a-wire and GaN NWs. In FIG. 2A, the band edge emission from GaN NWs excited at 352 nm decreases with increasing treatment time. After the first 30 minutes, the emission intensity decreases by a factor of about 4 and again by a factor of 1.6 after another 30 minutes. Subsequent exposures did not induce further change, suggesting, while not wishing to be limited by theory, that the major modification occurs during the first 60 minutes. Such decrease of PL emission can be ascribed, while not wishing to be limited by theory, to the creation of non-radiative recombination centers; a common feature in ion- and plasma-induced modification of nitride semiconductor thin films.^{15,16,25} Here, the non-radiative recombination defects are however restrained to the near-surface region because of the much lower range of kinetic energies of charged particles impinging onto the substrate (below a few eVs versus 100 eV up to a few keVs with ion beams and other plasma reactors). In addition, the defect creation dynamics is much slower than with ion beams and other plasma reactors because of the much lower number density of charged particles.²⁴

FIG. 2B shows the energy range that covers the GaN band edge emission for InGaN/GaN dot-in-a-wire nanostructures excited at 352 nm. Resonant Raman scattering from the first and second order E₁ LO mode can also be observed.⁵ As for nominally pure GaN NWs, both the GaN emission and the Raman peaks decrease with treatment time. However, an opposite trend is observed for the emission from the InGaN inclusions, as displayed in FIG. 2C. A significant increase of the PL emission occurs after multiple treatments with a saturation at longer treatment times. FIG. 2D shows the PL spectra from InGaN/GaN dot-in-a-wire samples recorded under below band gap excitation (405 nm). A significant increase of the emission is also observed with a saturation after about 90 minutes. While not wishing to be limited by theory, this strongly suggests that treatment in the late afterglow of a microwave N₂ plasma does not only contribute to the generation of non-radiative recombination centers in the near-surface region but also significantly modifies the InGaN dots buried in the GaN NW.

While a decrease of the PL emission from the GaN matrix is commonly observed due to the creation of non-radiative recombination centers in the near-surface region, the data presented in FIG. 2 indicates that other plasma-induced modification must occur to yield an increase of the emission from InGaN inclusions. Creation or passivation of defects at the NW surface could modify the absorption spectrum from the GaN matrix and thus the emission from the InGaN inclusions. To verify whether the band edge absorption of the GaN shell has shifted following the plasma treatment, PLE experiments were performed. FIG. 3 shows the normalized PLE spectra from InGaN/GaN dot-in-a-wire nanostructures obtained at an emission energy of 2.1 eV. The results are displayed for both an untreated sample and a sample exposed to the late afterglow of N₂ plasmas for 90 minutes. No shift of the GaN band edge can be observed, thus ruling out possible plasma-induced modification of the GaN absorption spectrum.

As described previously (see, for example, ref. no. 24), the number density of ground state N(⁴S) atoms can be significant in the late afterglow of microwave N₂ plasmas (number density of a few 10¹⁵ cm⁻³). Adsorption of N atoms and their transport from the NW topmost surface to the InGaN inclusions located much deeper in the volume could lead to a modification of the InGaN structure (for example by passivating grown-in defects, in particular N vacancies) and thus to an enhancement of the InGaN band edge emission. However, such a process, which requires that adsorbed species travel several tens of nanometers, is not likely to occur over the range of experimental conditions investigated since (i) the substrate was not externally heated and (ii) N(⁴S) atoms impinging onto the substrate only have small kinetic energies. Given the low neutral gas temperatures in the late afterglow of microwave N₂ plasmas (close to 300 K, see ref. no. 26), thermal annealing from the surrounding gas is clearly insufficient to induce such thermally-activated transport processes. This aspect was confirmed by recording the evolution of the substrate temperature using a thermocouple placed on the substrate holder. As presented in FIG. 4, the substrate temperature only slightly increases with treatment time, reaching at most 55° C. after 90 minutes. This is much lower than the typical activation energy barriers required for the diffusion of atoms in solids (typically a few eVs).

While the time-averaged substrate temperature displayed in FIG. 4 is clearly insufficient to induce the migration of atoms within the InGaN/GaN nanostructures by conventional thermal annealing, the de-excitation of long-lived N₂(A) metastables (with internal energies of 6 eV above the ground state level N₂(X), see FIG. 5) by collision with the surface represents a significant source of heat, at least within a very short time frame.

This aspect was examined in more detail by solving the heat-transfer equation assuming a heat source of 6 eV localized at the NW surface. Solutions of such equation in 1-dimension, assuming a thermal diffusivity in GaN of 0.43 cm² s⁻¹,²⁷ are presented in FIG. 6 for different time scales between 10⁻¹¹ and 10⁻⁸ s. To ensure significant heat transport from the topmost surface of the GaN matrix all the way to the InGaN inclusions, a minimal heat diffusion time of 10⁻¹⁰ s is used. Nonetheless, over the range of experimental conditions investigated, the substrate is not only exposed to N₂(A) metastables (typical number densities of N₂(A) are in the 10¹⁰-10¹¹ cm⁻³ range²⁸) that deexcite and then transfer significant amount of energy, but also to a much larger extent to ground state N₂(X) molecules (3×10¹⁷ cm⁻³ at 10 Torr) that tend to stabilize the surface temperature close to the one of the surrounding gas (about 300 K). At 10 Torr, assuming a mean free path for atom-atom collisions of about 5×10⁻⁶ m,²⁹ the average time between collisions of N₂(X) with the NWs is estimated to 10⁻⁸ s. Since this time is much longer than the one required for the deexcitation of metastables by collisions with the GaN surface and the energy transport all the way to the InGaN inclusions, significant energy can be deposited through this ultrafast process without significant rise of the time-averaged substrate temperature.

While not wishing to be limited by theory, a number of mechanisms can arise through such dynamic annealing in the late afterglow of microwave N₂ plasmas. As mentioned above, annealing in presence of adsorbed N atoms could passivate grown-in defects responsible of non-radiative recombination in the InGaN inclusions and thus yield to an increase of the PL emission, as seen in FIG. 3. For example, Kar et al.³⁰ reported improvement of the PL emission from tin oxide NWs following rapid thermal annealing at 700° C. in either N₂ or O₂. Both conditions have improved the crystalline quality of the NWs but the steady supply of oxygen atoms to the vacancy site during annealing in O₂ was found to be much more efficient. Yang et al.³¹ drew a similar conclusion for AlN NWs. Annealing treatments in N₂ environment have revealed much lower PL emission from defects ascribed to nitrogen vacancies in comparison to those realized in Ar environment. Shimogaki et al.³² studied the effect of nanosecond laser annealing in air on the PL spectra from phosphorous-implanted ZnO nanorods. Such ultrafast dynamic annealing was found to be much more effective in the recovery of the PL properties with respect to conventional annealing in a furnace. According to the authors, the ZnO layer damaged by P-ion implantation is melted and recrystallized by laser annealing without significant diffusion of implanted ions, resulting in the full compensation of the damaged layer.

Therefore both the adsorption of N atoms to passivate N vacancies and dynamic annealing to improve crystallization of the dot-in-a-wire nanostructure without significant diffusion at the InGaN/GaN interface are used to improve the emission properties from InGaN/GaN NWs.

III. Summary

In summary, nominally pure GaN nanowires and InGaN/GaN dot-in-a-wire nanostructures were exposed to the flowing afterglow of a N₂ microwave plasma characterized by high number densities of N atoms and N₂ metastables, but very low concentrations of charged particles. While the band edge emission from GaN NWs and the GaN matrix in InGaN/GaN heterostructures strongly decreased due to the creation of non-radiative recombination centers in the near-surface region, the emission from the InGaN inclusions increased significantly. PLE measurements indicate that such an increase cannot be ascribed to a shift of the GaN absorption edge. Rather, deep plasma-induced modification is ascribed to the deexcitation of N₂ metastables following their collision with the NWs that supply enough energy within a very short time frame (a few 10⁻¹⁰ s) to allow dynamic annealing. In combination with the adsorption of N atoms emanating from the plasma, while not wishing to be limited by theory, such annealing is expected to passivate grown-in defects responsible of non-radiative recombination in the InGaN inclusions.

### Example 2

### Tuning of the Emission Properties from InGaN/GaN Dot-in-a-Wire Nanostructures After Treatment in the Flowing Afterglow of a Microwave N₂—O₂ Plasma

The III-V nitride semiconductor family members and their alloys have been studied due to properties that make them stand out from other conventional III-V semiconductors. For example, they have a higher electron mobility, are suitable for high-temperature applications and exhibit wide direct bandgaps that allow to design heterostructures covering the electromagnetic spectrum from ultraviolet to infrared. Such materials are thus found in a wide range of optoelectronic devices such as but not limited to light-emitting diodes (LEDs) and laser diodes (LDs). InGaN/GaN dot-in-a-wire nanostructures are useful as they offer reduced defect densities because of lateral stress relaxation, larger active area due to the high surface-area-to-volume ratio, and improved LED efficiency because of quantum confinement. Surface modification of nanowires may, for example bestow upon them new or upgraded properties.

A new approach for post-growth functionalization of InGaN/GaN dot-in-a-wire nanostructures was explored in the studies of the present disclosure. As described in Example 1, samples were exposed to the flowing afterglow of a microwave plasma operated in nominally pure N₂ and plasma-induced modification of InGaN/GaN nanowires was analyzed by photoluminescence measurements at room temperature. While the band edge emission from GaN nanowires and the GaN matrix of the InGaN/GaN nanowires decreased due to the creation of non-radiative recombination centers in the near-surface region, the emission from the InGaN dots strongly increased. Photoluminescence excitation measurements indicate that such an increase cannot be explained by a plasma-induced shift of the GaN absorption edge. While not wishing to be limited by theory, it is rather ascribed to the adsorption of reactive N atoms and their transport inside the nanostructure, which passivate grown-in defects (in particular, N vacancies). The activation energy required for such incorporation results from the de-excitation of N₂ metastable species following their interaction with the GaN surface.

In the presence of O₂ in the N₂ plasma, emission properties can also be tuned energy-wise (red shift, as illustrated in FIG. 7, which shows the photoluminescence spectra from InGaN inclusions in InGaN/GaN dot-in-a-wire nanostructures excited at 355 nm after treatment to the flowing afterglow of a N₂—O₂ plasma). This indicates that post-growth treatments of nitride semiconductor nanostructures to the flowing afterglow of N₂—O₂ plasmas can not only improve the quality of as-grown samples, it can also be used to selectivity adjust the emission spectrum. This latter finding may, for example, be useful for applications which include but are not limited to LEDs, LDs and sensors.

### Example 3

### Post-Growth Doping of Graphene with the Flowing Afterglow of N₂ Plasma and N₂—O₂ Plasma

In this study, a new approach for post-growth doping of pristine graphene was examined. Samples were exposed to the flowing afterglow of a microwave N₂ plasma and plasma-induced modification of graphene samples was analyzed by FTIR, Raman, and XPS.

Photographs showing two views of the plasma-based process used are shown in FIG. 8. The photographs, taken during operation of the system, show the flowing afterglow configuration of a reduced-pressure N₂ plasma sustained by a propagating electromagnetic surface wave in the microwave regime. Labelled are the flowing afterglow \textcircled{1}; the surface wave plasma \textcircled{2}, the Surfatron plasma source \textcircled{3}; the afterglow treatment chamber \textcircled{4}; the gas inlet \textcircled{5}; the vacuum outlet \textcircled{6}; the flowing afterglow \textcircled{7}; and the graphene sample \textcircled{8}. This set-up can also be used for incorporation of other reactive atoms by introducing other feed gases in the N₂ plasma: for example O₂ for O atoms, H₂ for H atoms, and B₂H₆ for H and B atoms.

The chemical process is summarized in diagrams shown in FIGS. 9 and 10, showing the plasma-generated species impinging on the surface of a graphene sample and the resulting nitrogen chemical groups that have been detected after plasma treatment. The afterglow constituents are essentially N₂(X), N(⁴5), and N₂(A). As in Example 1, the metastable state N₂(A) is targeted to provide the activation energy required for incorporation of N atoms into the host materials following its de-excitation by collision with the surface. The three types of induced N groups are shown in more detail in FIGS. 10a Pyridinic N, 10b, pyrrolic N, and 10c aziridinic N.

As shown in the FTIR spectra displayed in FIG. 11, covalent amide and amine groups are uniformly introduced directly into graphene films. Developing with increased N uptake, peaks appear due to the formation of specific bond types that indicate the inclusion of reactive N atoms into the aromatic structure of graphene. The development of the benzenoid absorption band (750 cm⁻¹) is ascribed to the creation of aromatic cycles that contain nitrogen. This follows both the addition of reactive N atoms to the surface and the de-excitation of N₂ metastable species providing the activation energy for formation of heterocycles.

Raman spectroscopy provides information on the effect of plasma treatment on graphene, allowing for interpretation of the N incorporation dynamics. As shown in FIGS. 12a-12d, untreated graphene is characterized by a strong resonance peak around 2700 cm⁻¹ (G′-peak), attributed to large area uniformity across the honeycomb lattice, and smaller peak around 1600 cm⁻¹ (G-peak), commonly referred to as the graphitic peak produced by aromatic resonance. At short treatment times, an immediate decrease in the G′ peak is observed. Subsequent addition of N leads to a gradual increase of the D peak around 1300 cm⁻¹ ascribed to point defect formation (N interstitials) in the graphene lattice. The time evolution of the D-to-G′ ratio further indicates that graphene is treated through a steady, dose-wise process, which means that the incorporation process is reactant-limited, at least in the early stages.

Nitrogen doping is ascribed to both the adsorption of reactive N atoms (produced by electron-impact dissociation of the feed gas N₂ in the microwave plasma) and the de-excitation of N₂ metastables (produced both by electron-impact excitation of N₂ in the microwave plasma and by N₂ vibration-vibration pumping in the flowing afterglow; these N₂ metastable species provide the activation energy required for incorporation of reactive N adatoms). The quasi-absence of ions far in the flowing afterglow (late afterglow region) together with the low translation energies of species impinging onto the graphene sample leads to minimal ion-induced and thermal damage.

In FIG. 13, there is shown an ion bombardment setup, to guide the drafting of a drawing with the ion bombardment capability included. A second ion bombardment source can be added to facilitate the excitation of an inert gas, such as argon, to induce defects in graphene films and allow for control of the saturation point of incorporated N atoms.

The X-ray photoelectron spectroscopy data shown in FIG. 14 confirm the doping of graphene with N atoms. The two peaks at 398.6 eV and 399.5 eV correspond to the Pyridinic and Pyrrolic N, respectively. The presence of these peaks is directly indicative that N is incorporated into the conjugated honeycomb lattice. These results reveal that covalent amide groups are introduced directly into graphene films, with very low damage to the host nanomaterials or even amelioration of native defects.

The measurement of raman spectra (see FIG. 12) with increasing treatment time shows that the treatment does not diminish the large-area bonding over the initial treatment times that are required to introduce nitrogen atoms into aromatic configurations. Moreover, the Raman spectra taken from graphene directly on copper foil confirm that the G peak intensity is not affected by the treatment, thus confirming that cvd-grown graphene can be treated by this method directly on copper. The development of the D peak during treatment is linear, which provides further support for the claim that the treatment is limited to defects present in the sample, since the nitrogen aromatic content did not increase linearly over the same time. Finally, a steady shift in the peak position was found with treatment time, showing that the nitrogen flowing afterglow treatment does indeed modify the electronic structure.

Based on FIGS. 14a and 14b, XPS data, show the presence of aromatic nitrogen atoms. This data has been carefully analyzed to differentiate between aromatic and non-aromatic N, to account for the surface adsorption discussed in the Raman data and the mechanism. The peak assignments are as follow: N1s I, chemisorbed or weakly bonded N atoms deposited by flowing afterglow influx. N1s II is identified as Pyridinic N, an aromatic N group. N1s III is identified as pyrrolic N, an aromatic N group. N1s IV is identified as an amine group that is produced at the same time as the aromatic groups. FIG. 14a) shows the effect of treatment duration, highlighting the stable composition of aromatic components, labeled N1s II and N1s III, while both nonaromatic components, N1s I and N1s II respond to treatment time by increasing linearly in composition. FIG. 14(b) shows a typical XPS high resolution spectrum taken after treatment, showing N1s I-IV.

Direct evidence that the aromatic content is regulated by the defect density in as grown CVD was provided. By artificially increasing the defect density through ion bombardment, it was shown that Applicant can more than double the quantity of N introduced in the graphene honeycomb lattice in pyridinic form. This information is shown as three xps figures (FIGS. 15a, 15b and 15c), where the graphs are labeled a) for low defect density b) for increased defect density, showing a higher content of pyridinic N, and c) defect density higher still, where the size of defects starts to inhibit aromatic N introduction. FIG. 15d shows the relative atomic percentage values for the process of ion bombardment data, calculated by XPS. This shows that pyridinic N content increases by upwards of 300% and increases proportionally with defect density. The composition of surface amines, which are unaffected by defect density due to being added by a different reaction mechanism, does not change significantly with bombardment time.

Applicant has also demonstrated that through the introduction of UV light, new types of groups can be formed on the surface of graphene during treatment. The UV photons are produced in the plasma itself, and thus are inherent in the system, but are filtered out as the process is currently described. To this end, it is possible to modify the process to introduce another type of aromatic N. The XPS data to support this claim is shown in FIG. 16a), with N1s VI at approximately 401 eV representing the quaternary aromatic nitrogen component. FIG. 16b is a graphic demonstrating the type of group induced.

For example, the ions can be provided for tuning the defect density in nanomaterials by the same source, at a closer position relative to the sample, or by a secondary source placed closer relative to the sample, using an inert gas as the plasma gas or using the same dopant gas. In either case the defect density will be increased with bombardment treatment and the saturation point of atom incorporation will be augmented.

For example, for an inert gas such as argon, the accelerating voltage can be in the range of −1 to −150 VDC, and the duration of bombardment can be any time longer than 0 seconds. For example, in a plasma of argon at 500 mTorr and a flowrate of 400 sccm, the sample can be given an accelerating voltage of −100 V and ion bombardment can proceed for 3 seconds, and the result will be a 300% increase in N incorporated in aromatic pyridinic structures.

### Polymer Film Deposition

For example, by means of a short injection of a gaseous or vaporized precursor into the flowing afterglow, a plasma polymerized film coating can be deposited onto a target surface.

The precursor (for example a polymerizable moiety) can be injected using a simple liquid-vapor-equilibration vessel if it is liquid at room temperature, and it can be provided by a compressed source if the precursor is gaseous.

The precursor can be introduced using a metered flow of gas, or carrier gas for vapor precursors, that allows for precise control of precursor composition in the flowing afterglow after injection. Injection duration is dependent on the desired film thickness of the user. Significant deposition is possible after 1 minute.

For example, the carrier gas can be injected at a small fraction of the overall flowing afterglow flowrate, to avoid quenching the afterglow. This corresponds to about 1% to about 20% of the flowrate of the afterglow. For example, a flow of 20 sccm of nitrogen carrying an equilibrium content of pyrrole vapor can be injected into a nitrogen plasma afterglow flowing at 400 sccm, without quenching the afterglow.

For example, the target surface can be placed in a position to be face-on to the flowing afterglow, such that polymerized macromolecules deposit onto the surface by impinging flow. The precursor can be a simple hydrocarbon or a cyclic hydrocarbon, including aromatic hydrocarbons. For example, ethane and ethylene can be used as gaseous precursors, and benzene, pyrrole, and pyridine can be used as vaporized precursors.

For example, if the precursor injected is vaporized pyrrole, analysis of the deposited film by FTIR reveals the characteristic structure of a polycyclic aromatic macromolecule. This includes the peak at 1630 cm-1, which is produced by conjugated structures and indicates a conductive film. (see FIG. 17). The FTIR spectra shows the molecular structure of plasma deposited film using such a pyrrole monomer. The film matches the typical pattern of polypyrrole, including the conjugated structure band at 1630 cm-1^{33,34}. This demonstrates that the film has electrical conductivity.

For example, injection into the flowing afterglow of the microwave plasma can be carried out, as demonstrated by optical emission spectroscopy, as shown in FIG. 18. The presence of C—N excitation emission in a nitrogen flowing afterglow indicates that partial decomposition of the precursor and subsequent plasma reactions occur during the process. For this reason, the polymerization reaction is known to begin in the gas phase, prior to surface deposition.

This Optical Emission Spectrum of the plasma at the point of injection, showing excited vibrational states of CN. This shows that the plasma is an integral part of the polymerization chemistry, and that the controlled dissociation of some of the monomer is required to initiate the reaction. This Optical Emission Spectrum of the plasma at the point of injection, showing excited vibrational states of CN. This shows that the plasma is an integral part of the polymerization chemistry, and that the controlled dissociation of some of the monomer is required to initiate the reaction.

For example, procedures where the vaporized or gaseous precursor is injected in a flow of non-energized gas, i.e. no plasma afterglow, revealed no significant polymer structure in FTIR, as shown in FIG. 19. This confirms that flowing afterglow is responsible for the structure seen in the FTIR spectra, and that a deposited film of the precursor itself will not produce a conductive film. Injection into the flowing afterglow of the plasma is a necessary first step for the formation of a polymer film on the target surface. This Infrared spectra shows role of plasma polymerization in film structure. Injection into the flowing afterglow produces characteristic peaks, while injection into inert nitrogen flowing at the same rate does not result in any appreciable film deposition.

FIG. 20 is a schematic diagram of the setup, showing the injection point in the late afterglow. Not shown is the vessel holding the liquid precursor. This is a combination of possible means to provide a gaseous or vaporised chemical precursor into the flowing afterglow. In FIG. 20, A represents a surfatron, B the microwave plasma, C an early afterglow, D a late afterglow and E a treatment chamber.

For example, a subsequent plasma treatment can be used to provide further energy for annealing the polymer and removing volatile surface species. The duration of the post-treatment can be short, for example about 1 to about 15 minutes, about 1 to about 10 minutes or about 1 to about 5 minutes. For example, a post-treatment of 5 minutes has been shown to reduce the signals of water vapor and other species.

### Further Discussion of Examples 1-3

The present studies used a non-destructive method for atom incorporation into materials such as nanomaterials using the flowing afterglow of N₂-based plasmas at reduced pressure. The method can, for example, be used to incorporate nitrogen (and other) atoms into macromolecular and crystal surfaces using the flowing afterglow of N₂ plasmas in which N₂ metastable species are present in significant amount. The use of both reactive atoms (produced by electron-impact dissociation of the feed gases in the microwave plasma) and N₂ metastable species (produced both by electron-impact excitation of N₂ in the microwave plasma and by N₂ vibration-vibration pumping in the flowing afterglow) for this purpose is a departure from what is currently the state of the art in atomic manipulation, mainly because N₂ metastable species provide activation energy for covalent incorporation of reactive adatoms, while leaving the translational or kinetic energy of both the impinging particles and the materials undisturbed. This method is made possible by the existence of a metastable state of the nitrogen molecule (labeled A³ in FIG. 5) that does not de-excite spontaneously back to the ground state by emission of a photon. In effect, the nitrogen metastable species are held in an excited state, with approximately 6 eV of potential energy, until a subsequent collision, either with other plasma particles or with a surface, can trigger the de-excitation of the electron and its subsequent demotion back to the ground state. Collisions between reactive atoms and N₂ metastable species (with temperatures close to room temperature), and a large scale macromolecule such as graphene or a solid crystalline surface produce introduced nitrogen species that are otherwise impossible, without providing much greater energy to the entire atom in the form of kinetic or translational energy. As a result, specific surface chemistry can be targeted without the excessive creation of damage as in conventional processes relying on reactive species with high kinetic energies, for example, ion implantation and neutral beam implantation.

The methods of the present studies can be used, for example, to tune the physical and chemical properties of nanomaterials, for example, InGaN/GaN dot-in-a-wire nanostructures as well as to prepare N-doped graphene. Other reactants could also be introduced, for example H₂ and B₂H₆ for hydrogen and boron doping of nanomaterials, respectively. Such reactive B and H atoms are common dopants, for example, for bulk semiconductor applications.

The processes of the present studies may, for example allow for the production of nitrided nanomaterials under conditions that are simpler to produce than known methods which may, for example, bring concurrent reductions in operating costs and the cost of expensive materials, such as rare gases, that are used by ultra-high vacuum atom beam technology. The processes of the present studies may also, for example be capable of producing larger treated surfaces, by use of flow vectoring to direct the flowing afterglow over larger surfaces. The processes of the present studies may, for example, produce higher quality nitride nanomaterials than known atom-beam methods, in that the native electronic and thermal properties of the host nanomaterials are not adversely affected by bombardment degradation and thermal damage.

In conventional low-pressure plasma reactors used for deposition and etching of thin films in the microelectronic and optical industries, energetic ions accelerated in the sheath surrounding the sample are known to produce an extensive cascade of defects in materials following their impact with the surface. For treatments of highly sensitive nanomaterials such as nanowires, nanofilms or macromolecular nanostructures, these highly energetic species are too aggressive and typically destroy the materials, making plasma-based processes inappropriate. Therefore there is a need for new, plasma-based methods for post-growth functionalization of nanomaterials. The unique combination of reactive atoms (produced by electron-impact dissociation of the feed gases) and N₂ metastable species (produced both by electron-impact excitation of N₂ in the plasma and by N₂ vibration-vibration pumping in the flowing afterglow), with minimal populations of charged species in the downstream region is a promising medium for such applications, as evidenced by the results of the studies of the present disclosure on InGaN/GaN dot-in-a-wire nanostructures and graphene samples. For example, N atoms can be covalently added into nanomaterials, without inducing excessive damage or rearrangement to the host structure, under conditions that are easy to maintain and with minimal power requirements. Maintaining the native structure is useful for preserving the properties of the host material, such as thermal or electrical conductivity, optical properties, etc.

The reactor that was used for the N₂ plasmas was devised to emphasize the presence of both N atoms and N₂ metastable species at the location of the sample in the downstream region of the plasma, with minimal populations of charged species in this region to prevent ion-induced damage. All species interacting with the samples have mean kinetic energies (or temperatures) close to room temperature (300 K), which may, for example, make the process compatible with heat-sensitive materials such as polymers.

The methods of the present disclosure, may, for example be useful for the development of organic electronics, inorganic semiconductors and biocompatible conductive surfaces. This approach of doping nitrogen (and other reactive atoms) into surfaces with the activation energy provided by the de-excitation of N₂ metastable species is a departure from conventional methods and provides a product that may be useful for fields such as the semiconductor industry, electronics, sensor surfaces, solar cells, analytical diagnostics, and optical filtering. Nitrogen-doped materials may be a useful product and they may also be the foundation materials for new nano-composites. The list includes but is not limited to organic light emitting transistors, neuro-electrode materials, photo-luminescent devices as well as electrically conductive polymer plastics.

It was found that the methods of the present disclosure are non-destructive methods. Moreover, such methods are methods that can be carried out after growth of said material (i.e. post-growth methods). It was also found that the methods of the present disclosure are methods that allow for inserting said atom into said material. For example, such methods allow for inserting said atom into said material rather than solely binding said atom to the surface of said material. For example, FIG. 12 clearly shows the presence of pyridinic and pyrrolic bonds that indicates a particular kind of incorporation into graphene, where the N atom participates in the hexagonal lattice of the graphene macromolecule.

While a description was made with particular reference to the specific embodiments, it will be understood that numerous modifications thereto will appear to those skilled in the art. Accordingly, the above description and accompanying drawings should be taken as specific examples and not in a limiting sense.

### FULL CITATIONS FOR DOCUMENTS REFERRED TO IN THE SPECIFICATION

¹C. Wetzel, B. Gil, M. Kuzuhara and M. Manfra, GaN, AlN, InN and their Alloys, UK: Cambridge University Press, 2005, pp. 231-237.
²P. Schlotter, J. Baur, C. Hielscher, M. Kunzer, H. Obloh, R. Schmidt and J. Schneider, “Fabrication and characterization of GaN/InGaN/AlGaN double heterostructure LEDs and their application in luminescence conversion LEDs,” Switzerland: Materials Science and Engineering, vol. B59, no. 1-3, pp. 390-394, 1999.
³I. Akasaki, “GaN-based UV/blue light emitting devices,” in Proceedings of the Nineteenth International Symposium, Japan: Gallium Arsenide and Related Compounds, 1992.
⁴P. Hsu, K. Kelchner, A. Tyagi, R. Farrell, D. Haeger, K. Fujito, H. Ohta, S. DenBaars, J. Speck and S. Nakamura, “InGaN/GaN blue laser diode grown on semipolar (3031) free-standing GaN substrates,” Japan: Applied Physics Express, vol. 3, no. 5, p. 10DUMY, 2010.
⁵Y. Kamali, B. Walsh, J. Mooney, H. Nguyen, C. Brosseau, R. Leonelli, Z. Mi and P. Kambhampati, “Spectral and spatial contributions to white light generation from InGaN/GaN dot-in-a-wire nanostructures,” Journal of Applied Physics, vol. 114, no. 16, p. 164305, 2013.
⁶Z. Mi, H. Nguyen, S. Zhang, K. Cui and M. Djavid, “Molecular beam epitaxial growth and characterization of InGaN/GaN dot-in-a-wire nanoscale heterostructures: Toward ultrahigh efficiency phosphor-free white light emitting diodes,” USA: Proceedings of SPIE—The International Society for Optical Engineering, vol. 8634, p. 8634B, 2013.
Z. Mi, Y. Chang, J. Wang and F. Li, “High efficiency green, yellow, and amber emission from InGaN/GaN dot-in-a-wire heterostructures on Si(111),” USA: Applied Physics Letters, vol. 96, no. 1, p. 013106, 2010.
⁸M. Zhang, “InGaN/GaN nanowire green light emitting diodes on (001) Si substrates,” USA: 2010 68th Annual Device Research Conference (DRC 2010), pp. 229-230, 2010.
⁹M. Zhang, “Catalyst-free InGaN/GaN nanowire light emitting diodes grown on (001) silicon by molecular beam epitaxy,” USA: Nano Letters, vol. 10, no. 9, pp. 3356-3359, 2010.
¹⁰A. Kikuchi, M. Tada, K. Miwa and K. Kishino, “Growth and characterization of InGaN/GaN nanocolumn LED,” USA: Proceedings of the SPIE—The International Society for Optical Engineering, vol. 6129, no. 1, pp. 612905-1-8, 2006.
¹¹E. Cimpoiasu, E. Stern, R. Klie, R. Munden, G. Cheng and M. Reed, “The effect of Mg doping on GaN nanowires,” UK: Nanotechnology, vol. 17, no. 23, pp. 5735-5739, 2006.
¹²D. Q. Fang, A. Rosa, T. Frauenheim and R. Zhang, “Band gap engineering of GaN nanowires by surface functionalization,” USA: Applied Physics Letters, vol. 94, no. 7, p. 073116, 2009.
¹³C. Hsu, A. Ganguly, C.-P. Chen, C.-C. Kuo, P. Paskov, P. Holtz, L.-C. Chen and K.-H. Chen, “Optical properties of functionalized GaN nanowires,” USA: Journal of Applied Physics, vol. 109, no. 5, p. 053523, 2011.
¹⁴S. Pearton, J. Zolper, R. Schul and F. Ren, “GaN: processing, defects, and devices,” USA: Journal of Applied Physics, vol. 86, no. 1, pp. 1-78, 1999.
¹⁵M.-G. Chen, K. Nakamura, Y. Nakano, G.-H. Zhang and H. Sugai, “In situ Probe of GaN Film Surfaces under Plasma Conditions by Photoluminescence Technique,” Japan: Applied Physics Express, vol. 5, no. 7, p. 076201, 2012.
¹⁶S. Chen, Y. Lu, R. Kometani, K. Ishikawa, H. Kondo, Y. Tokuda, M. Sekine and M. Hori, “Photoluminescence recovery by in-situ exposure of plasma-damaged n-GaN to atomic hydrogen at room temperature,” USA: AIP Advances, vol. 2, no. 2, p. 022149, 2012.
¹⁷Y. Shao, S. Zhang, M. H. Engelhard, G. Li, G. Shao, Y. Wang, J. Liu, I. A. Aksay and Y. Lin, “Nitrogen-doped graphene and its electrochemical applications,” Journal of Materials Chemistry, vol. 20, pp. 7491-7496, 2010.
¹⁸A. Felten, A. Eckmann, J.-J. Pireaux, R. Krupke and C. Casiraghi, “Controlled modification of mono- and bilayer graphene in O₂, H₂ and CF₄ plasmas,” Nanotechnology, vol. 24, 355705, 2013.
¹⁹H. P. T. Nguyen, S. Zhang, K. Cui, X. Han, S. Fathololoumi, M. Couillard, G. Botton and Z. Mi, “P-type modulation doped InGaN/GaN dot-in-a-wire white-light emitting diodes monolithically grown on Si(111),” USA: Nano Letters, vol. 11, no. 5, pp. 1919-1924, 2011.
²⁰H. P. T. Ngyen, M. Djavid, K. Cui and Z. Mi, “Temperature-dependent nonradiative recombination processes in GaN-based nanowire white-light-emitting diodes on silicon,” UK: Nanotechnology, vol. 23, no. 19, p. 194012, 2012.
²¹M. Moisan, Z. Zakrzewski and R. Pantel, “The theory and characteristics of an efficient surface wave launcher (surfatron) producing long plasma columns,” UK: Journal of Physics D (Applied Physics), vol. 12, no. 2, pp. 219-237, 1979.
²²M. Moisan, M. Boudam, B. Saoudi and A. Ricard, “Characterization of the flowing afterglows of an N2-O2 reduced-pressure discharge: setting the operating conditions to achieve a dominant late afterglow and correlating the NOβ UV intensity variation with the N and O atom densities,” UK: Journal of Physics D—Applied Physics, vol. 40, no. 6, pp. 1694-1711, 2007.
²³V. Guerra, P. Sa and J. Lourreiro, “Nitrogen pink afterglow: the mystery continues,” UK: Journal of Physics Conference Series, vol. 63, no. 1, p. 11, 2007.
²⁴J. Afonso Ferreira, L. Stafford, R. Leonelli and A. Ricard, “Electrical characterization of the flowing afterglow of N2 and N2/O2 microwave plasmas at reduced pressure,” Journal of Applied Physics, vol. 115, p. 163303, 2014.
²⁵T. Langer, H. Arlen, A. Kruse, H. Bremers, U. Rossow and A. Hangleiter, “Strain-induced defects as nonradiative recombination centers in green-emitting GaInN/GaN quantum well structures,” USA: Applied Physics Letters, vol. 103, no. 2, p. 022108, 2013.
²⁶A. Ricard, N. Kang, M. Lee and S. G. Oh, “Effect of controlled O2 impurities on N2 afterglows of RF discharges,” Netherlands: Current Applied Physics, vol. 12, no. 6, pp. 1448-1453, 2012.
²⁷V. Bougrov, M. Levinshtein, S. Rumyantsev and A. Zubrilov, “Properties of Advanced Semiconductor Materials GaN, AlN, InN, BN, SiC, SiGe,” New-York, John Wiley & Sons Inc., 2001, pp. 1-30.
²⁸A. Ricard, S. Oh and V. Guerra, “Line-ratio determination of atomic oxygen and (A3E+u) metastable absolute densities in an RF nitrogen late afterglow,” Royaume-uni: Plasma Sources, Science and Technology, vol. 22, no. 3, p. 035009, 2013.
²⁹Hirschfelder, Curtiss and Bird, Molecular Theory of Gases and Liquids, New-York: Wiley, 1954.
³⁰A. Kar, M. Stroscio, M. Dutta, J. Kumari and M. Meyyappan, “Growth and properties of tin oxide nanowires and the effect of annealing conditions,” UK: Semiconductor Science and Technology, vol. 25, no. 2, p. 024012, 2010.
³¹J. Yang, H. Na, H. Kim, M. Kebede, R. Choi, J. Kebede, C. Lee and H. Kim, “Photoluminescence Studies of Aluminum Nitride Nanowires,” Poland: Acta Physica Polonica A, vol. 119, no. 2, pp. 125-127, 2011.
³²T. Shimogaki, K. Okazaki, D. Nakamura, M. Higashihata, T. Asano and T. Okada, “Effect of laser annealing on photoluminescence properties of Phosphorus implanted ZnO nanorods,” USA: Optics Express, vol. 20, no. 14, pp. 15247-52, 2012.
³³H. Chitte, G. Shinde, N. Bhat and V. Walunj, “Synthesis of Polypyrrole Using Ferric Chloride (FeCl₃) as Oxidant Together with Some Dopants for Use in Gas Sensors,” Journal of Sensor Technology, Vol. 1 No. 2, 2011, pp. 47-56.
³⁴Cruz, G. J., J. Morales, and R. Olayo. “Films obtained by plasma polymerization of pyrrole.” Thin solid films 342, no. 1 (1999): 119-126.

1. A method for atom incorporation into a material, comprising:
subjecting a gas comprising said atom to conditions to obtain a flowing plasma afterglow; and
exposing said material to said flowing plasma afterglow.

2. The method of claim 1, wherein said gas is subjected to an electromagnetic field in the microwave regime to obtain a high-density plasma with a flowing plasma afterglow.

3. The method of claim 2, wherein said electromagnetic field, has a frequency of about 433 MHz to about 3 GHz.

4-5. (canceled)

6. The method of claim 1, wherein said atom incorporated into said material is N, O, B, H or mixtures thereof and said gas comprises N₂, O₂, B₂H₆, H₂ or mixtures thereof, respectively.

7. The method of claim 1, wherein said atom incorporated into said material is a mixture of N and O and said gas consists essentially of a mixture of N₂ and O₂.

8. The method of claim 1, wherein said atom incorporated into said material is N and said gas consists essentially of N₂.

9-11. (canceled)

12. The method of claim 1, wherein said method is carried out at a total gas pressure of from about 1 Torr to about 20 Torr.

13. (canceled)

14. The method of claim 1, wherein said flowing plasma afterglow is a late afterglow.

15. The method of claim 1, wherein said flowing plasma afterglow has a positive ion density of about 10⁵ cm⁻³ to about 10¹⁰ cm⁻³.

16-22. (canceled)

23. The method of claim 1, wherein said material comprises graphene, a nanomaterial, a metal surface, a crystal surface, a polymer or a combination thereof.

24. (canceled)

25. The method of claim 23, wherein said material comprises graphene and copper, nickel, diamond or sapphire.

26-27. (canceled)

28. The method of claim 23, wherein said material comprises a nanomaterial chosen from a nanowire, a nanotube, a nanofilm and mixtures thereof.

29. The method of claim 1, wherein said atom incorporated into said material is N, thereby forming N-containing aromatic groups or N-containing heterocycles.

30. (canceled)

31. The method of claim 1, wherein said atom incorporated into said material is N, thereby forming pyridinic groups and/or pyrrolic groups.

32. (canceled)

33. The method of claim 1, wherein said atom incorporated into said material is N, thereby forming amide groups, amine groups or aziridinic groups.

34-40. (canceled)

41. The method of claim 1, further comprising treating said material with ions bombardment so as to increase defect density into said material and/or atom incorporation into said material.

42. The method of claim 1, wherein said method comprises applying a DC voltage on a holder for holding said material so as to accelerate inert positive ions to the surface of said material.

43. (canceled)

44. The method of claim 1, wherein said method comprises, before exposing said material to said flowing plasma afterglow, contacting said plasma afterglow with a carbon-containing substance effective for polymerizing.

46-54. (canceled)

55. The method of claim 23, wherein said nanomaterial comprises a InGaN/GaN nanomaterial.

56-57. (canceled)

58. The method of claim 1, wherein said method is a method carried out after growing of said material.

59-67. (canceled)

68. An atom-doped material prepared by the method for atom incorporation into a material of claim 1.

69-73. (canceled)

74. A method for decreasing defects in a nitride semiconductor nanostructure, comprising exposing said nitride semiconductor nanostructure to a flowing plasma afterglow of a plasma obtained from a gas comprising N₂.

75. A method for tuning the emission spectrum of a nitride semiconductor nanostructure, comprising exposing said nitride semiconductor nanostructure to a flowing plasma afterglow of a plasma obtained from a gas comprising N₂ and O₂.
